(19) United States
(12) Patent Application Publication
(10) Pub. No.: US 2005/0034663 A1
(43) Pub. Date: Feb. 17, 2005

(54) Vacuum film formation method and vacuum film formation device

(76) Inventor: Katsuya Yamamoto, Kariya-shi (JP)

Correspondence Address: Morgan & Finnegan . L.L.P., Three world Financial Center, New York ,, NY, 10281-2101, US

(21) Appl. No.: 10/899,377

(22) Filed: Jul. 26, 2004

(30) Foreign Application Priority Data
Jul. 28, 2003 (JP) P2003-202147

(51) Int. Cl. B05D 5/06; C23C 16/00

(52) U.S. Cl. 118/718; 427/255.5; 427/69

(57) ABSTRACT

The present invention provides a vacuum film formation method for forming a deposition layer by facing a deposition source, which emits a deposition material, and a substrate towards each other; moving the deposition source and the substrate relatively to each other, while keeping an interval between the deposition source and the substrate; and depositing the deposition material from the deposition source onto the substrate. The vacuum film formation method includes the steps of: emitting the deposition material of a constant width from the deposition source in the shape of a strip; and moving the deposition source and the substrate relatively to each other in directions including a first direction, which is orthogonal to a width direction of the strip of the deposition material emitted in the shape of the strip, and a second direction different from the first direction.

### BACKGROUND OF THE INVENTION

The present invention relates to a vacuum film formation method and a device using the same.

An organic electroluminescent (EL) element includes an anode and a cathode, which are provided on a substrate, and an organic layer containing a light-emitting organic material, which is formed between the anode and cathode. Organic EL elements have been known to be capable of emitting light from the organic layer by applying a voltage between the anode and cathode.

For an organic EL element employing a small molecular organic material in the above-stated configuration, it is typical that the organic material is deposited using a vacuum deposition process on the substrate to form the organic layer.

In the vacuum deposition process, an organic material for forming an organic layer is housed in a deposition source with outlets. The deposition source is heated in a chamber, in which a prescribed vacuum level is maintained, to emit the evaporated organic material through the outlets. The emitted organic material is deposited on the substrate apart from the deposition source.

In a typical film formation method using a conventional vacuum deposition process, a film formation device, such as device 200 shown in FIG. 13, has been used. For example, Japanese Unexamined Patent Publication No. 2003-77662, page 3 and FIGS. 1, 2 and 18 thereof use such a film formation device. Japanese Unexamined Patent Publication No. 2003-77662 is hereinafter referred to Patent Document 1

The film formation device 200 comprises a chamber 203 including deposition sources 201, which have outlets 202 and a rotatable substrate holder 205, which is capable of supporting a substrate 204 together with a mask 206.

In the film formation method using the film formation device 200, an organic material constituting an organic layer is housed in the deposition source 201. The deposition source 201 is heated in the chamber 203, in which a predetermined vacuum level is maintained, the organic material is vaporized or sublimed and emitted through the outlets 202. The substrate 204 is horizontally rotated (rotates on its axis) together with the mask 206 during deposition by the substrate holder 205, and the organic material emitted from the deposition source 201 is deposited on the substrate 204 to form an organic layer.

The reason the substrate 204 is rotated during deposition is that a distribution of film thickness over the substrate 204 needs to be as uniform as possible. In particular, in a case of an organic EL element, when the degree of uniformity of the distribution of film thickness over the substrate 204 is insufficient, there arise problems due to the fact that brightness performance is degraded, functional stability cannot be assured, and lifetime of the element is shortened.

However, the substrate 204 having the above configuration is typically shaped into a square. Accordingly, when the substrate 204 is rotated, a portion of the organic material is not deposited on a peripheral portion of the substrate 204, resulting in waste of the expensive organic material.

Further, since the substrate 204 is rotated, the chamber 203 housing the deposition source 201 and the substrate 204 is made larger, because a space is needed for rotating the substrate 204 and a problem of enlarging the size of the film formation device 200 occurs.

Although rotation of the substrate 204 is intended to enhance uniformity of the distribution of film thickness of the organic layer, the film thickness on different portions of the substrate 204 actually varies. For instance, comparison of a portion around the center of the substrate 204 and a portion farthest from the center makes it apparent that there is a distinguished difference between film thickness of those portions.

Accordingly, this technique is inadequate because the distribution of the film thickness of the organic layer over the substrate 204 needs to be evened out.

As a conventional technique (hereinafter “conventional technique 1”) overcoming the above-stated problems, a technique has been known in which a deposition source is elongated in a longitudinal direction. The deposition source is caused to emit an organic material in the shape of a strip, and the substrate moves in relation to the deposition source in a direction orthogonal to the longitudinal direction of the deposition source. For example, please refer to the Patent Document 1.

In a deposition source housing of the deposition source, a plurality of outlets are arranged at a predetermined interval along the longitudinal direction thereof. Movement of the substrate allows the organic layer to be formed on the substrate, which has a width corresponding substantially to the longitudinal dimension of the deposition source housing.

Therefore, according to the film formation method using the conventional technique 1, it is said that the distribution of the film thickness of the organic layer formed on the substrate is relatively uniform.

Further, in a technique similar to the conventional technique 1, a film formation method has been also known in which a deposition source elongated in a longitudinal direction is employed. The deposition source is moved in a direction orthogonal to the longitudinal direction of the deposition source, and a deposition layer is formed on a substrate. For example, please refer to Japanese Unexamined Patent Publication No. 2001-247959, page 3 and FIG. 1 thereof.

Moreover, according to another conventional technique (hereinafter conventional technique 2), a plurality of deposition sources are disposed so as to correspond to regions for formation of an organic layer on a substrate. A plurality of outlets are provided in the individual deposition sources, and an organic material is emitted through the outlets, while the substrate is moved in an oscillating fashion in the same plane as the substrate. For example, please refer to Japanese Unexamined Patent Publication No. 2002-184571, pages 3-5 and FIGS. 2, 6 thereof.

According to the film formation method using the conventional technique 2, the method is said to effectively reduce variations in the distribution of the film thickness of the organic layer formed on the substrate.

However, in the above-stated conventional technique 1, there arises a problem due to the fact that variations are still present in the distribution of the film thickness of the organic layer formed on the substrate.

That is, although the deposition source, as a whole, emits the organic material in the shape of a strip from the deposition source, the individual outlets, which face the substrate of the deposition source, leave linear trails, which are relative to the direction of movement of the substrate. For example, when the substrate on which the organic layer has been formed is cut in a direction orthogonal to the direction of movement of the substrate, the organic layer is thick on a line extending from and directly below the outlet and is thin on a line extending from a portion between the adjacent outlets and extending directly below the portion. Therefore, the thickness of the organic layer is not uniform.

Such a phenomenon becomes more distinguished as a distance between the deposition source and the substrate becomes shorter.

Further, conventional technique 2 is time-consuming because a plurality of deposition sources corresponding to regions for formation of the organic layer on the substrate must be provided.

In particular, when enlargement of the substrate is expected, a number of deposition sources could be used in combination with one another. In this case, the above-mentioned problems cannot be avoided. These time-consuming characteristics become increasingly prevalent, when the individual deposition sources are adjusted relatively to the substrate or the individual deposition sources are uniformly heated in order to cause organic materials to be emitted from the individual deposition sources, which are to be placed under exactly the same conditions.

Furthermore, since a number of the deposition sources are provided, which correspond to the regions for formation of the organic layer on the substrate, a problem of increasing the manufacturing cost of a film formation device occurs.

### SUMMARY OF THE INVENTION

The present invention is directed to a vacuum film formation method that ensures uniformity of a distribution of film thickness of a deposition layer and a vacuum film formation device using the same.

The present invention provides a vacuum film formation method for forming a deposition layer by facing a deposition source, which emits a deposition material, and a substrate towards each other; moving the deposition source and the substrate relatively to each other, while keeping an interval between the deposition source and the substrate; and depositing the deposition material from the deposition source onto the substrate. The vacuum film formation method includes the steps of: emitting the deposition material of a constant width from the deposition source in the shape of a strip; and moving the deposition source and the substrate relatively to each other in directions including a first direction, which is orthogonal to a width direction of the strip of the deposition material emitted in the shape of the strip, and a second direction different from the first direction.

The present invention also provides a vacuum film formation device for forming a deposition layer by emitting a deposition material on a substrate arranged in a chamber, in which a prescribed vacuum is maintained. The vacuum film formation device includes a deposition source and a relative movement enabling means. The deposition source is arranged in the chamber facing the substrate and emits the deposition material of a constant width on the substrate in the shape of a strip. The relative movement enabling means moves the deposition source and the substrate relatively to each other in directions including a first direction, which is orthogonal to a width direction of the strip of the deposition material emitted in the shape of a strip, and a second direction different from the first direction.

Other aspects and advantages of the invention will become apparent from the following description, taken in conjunction with the accompanying drawings, which illustrate by way of example the principles of the invention.

### BRIEF DESCRIPTION OF THE DRAWINGS

The features of the present invention that are believed to be novel are set forth with particularity in the appended claims. The invention, together with objects and advantages thereof, may best be understood by reference to the following description of the presently preferred embodiments, together with the accompanying drawings, in which:

FIG. 1 is a schematic sectional view illustrating an organic electroluminescent element according to a first embodiment of the invention;

FIG. 2 is a schematic perspective view illustrating a film formation device according to the first embodiment of the invention;

FIG. 3 is a side view illustrating the film formation device, which is partially cut away, according to the first embodiment of the invention;

FIG. 4 is a front view illustrating the film formation device, which is partially cut away, according to the first embodiment of the invention;

FIG. 5 is a schematic perspective view illustrating a film formation device according to a second embodiment of the invention;

FIG. 6 is a schematic perspective view illustrating a film formation device according to a third embodiment of the invention;

FIG. 7 is a schematic perspective view illustrating a film formation device according to a fourth embodiment of the invention;

FIG. 8 is a schematic plane view illustrating a film formation device according to a fifth embodiment of the invention;

FIG. 9 is a schematic perspective view illustrating the film formation device according to the fifth embodiment of the invention;

FIG. 10 is a schematic perspective view illustrating a film formation device according to a sixth embodiment of the invention;

FIG. 11 is a schematic perspective view illustrating a film formation device according to a seventh embodiment of the invention;

FIG. 12 is a schematic perspective view illustrating a film formation device according to an eighth embodiment of the invention; and

FIG. 13 is a partially enlarged schematic side view illustrating a prior art film formation device.

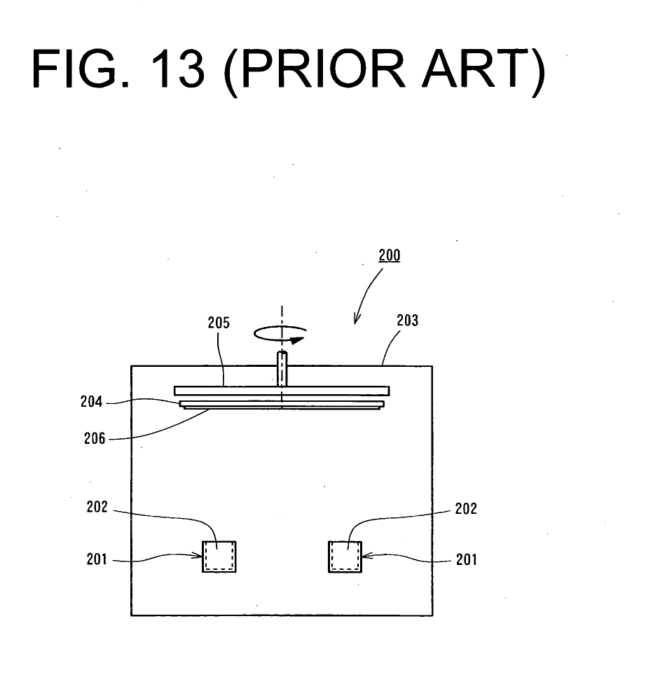

### DETAILED DESCRIPTION OF THE PREFERRED EMBODIMENTS

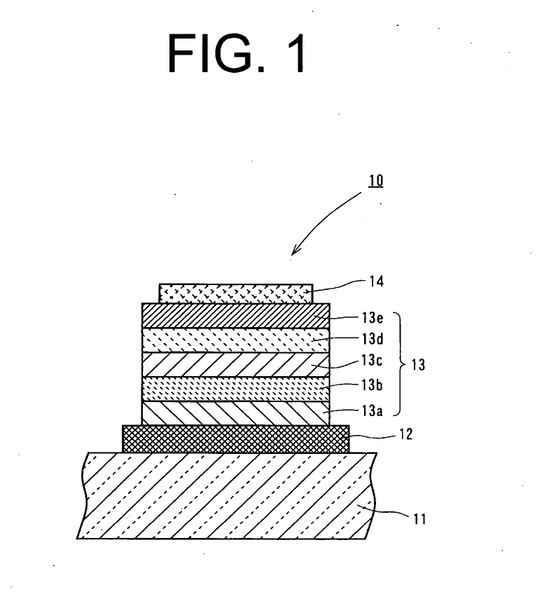

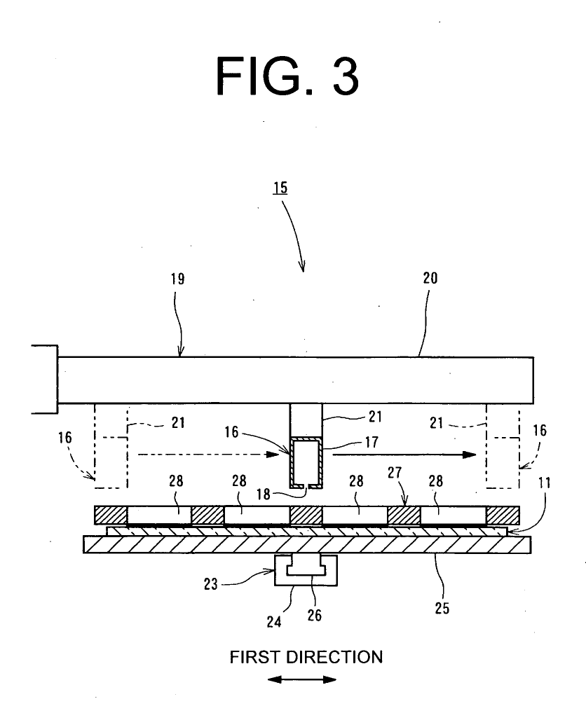

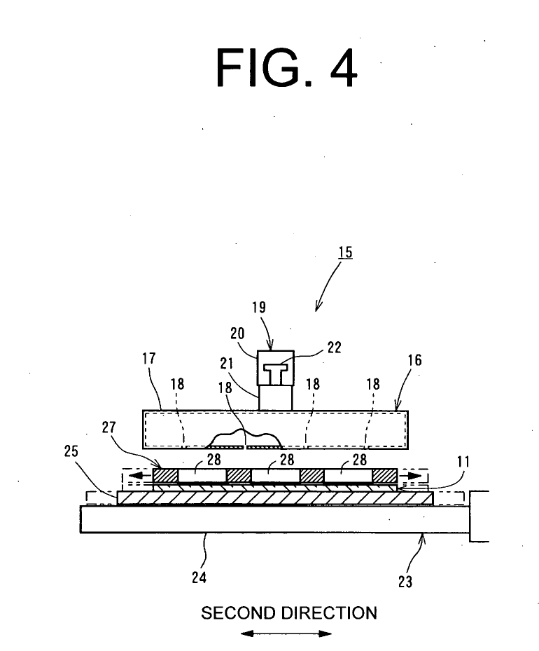

A first embodiment of the invention will be explained below with reference to FIGS. 1 to 4.

In this embodiment, an example in which an organic layer of an organic EL element is formed as a deposition layer will be explained.

First, a general explanation of the organic EL element is presented and an organic EL element 10 shown in FIG. 1 essentially includes a glass substrate 11, an anode 12, an organic layer 13, and a cathode 14.

The glass substrate 11 allows visible light to transmit therethrough and the anode 12 is arranged as a transparent conductive layer formed on one surface of the glass substrate 11.

In this embodiment, the anode 12 is made of ITO (Indium Tin Oxide) and is formed, for example, by sputtering.

Then, in this embodiment, as shown in FIG. 1, laminated on the anode 12 are a hole injection layer 13a, a hole transport layer 13b, a luminous layer 13c, an electron transport layer 13d, and an electron injection layer 13e in this order. In this embodiment, a combination of these layers is referred to generally as an organic layer 13.

All the layers 13a to 13e are of different types of organic materials and each layer is formed by depositing an organic material as a deposition material using a vacuum deposition process.

The term “substrate” used herein includes at least a plate member such as the glass substrate 11 on which the anode 12 will be formed and a deposition material such as an organic material will be evaporated.

For instance, the glass substrate 11 having only the anode 12 formed thereon, or the glass substrate 11 having the hole injection layer 13a, the hole transport layer 13b, the luminous layer 13c, the electron transport layer 13d, and the anode 12 formed thereon could be included in the conceptual expression “substrate” used herein.

Formed on the organic layer 13 is the cathode 14. The cathode 14 is an electrode for injecting electrons into the electron injection layer 13e, and is made typically of a metallic material with a small work function, such as lithium or aluminum.

An organic EL element 10 thus constructed is operated when direct-current voltage is applied between the anode 12 and the cathode 14 to inject holes from the anode 12 to the luminous layer 13c and simultaneously inject electrons from the cathode 14 to the luminous layer 13c.

Then, the electrons and holes are recombined in the luminous layer 13c and are transferred into an excited state. Energy emitted during the excited state results in a light emission phenomenon appearing in the luminous layer 13c.

A film formation device 15 for formation of the organic layer 13 of the organic EL element 10 will now be explained.

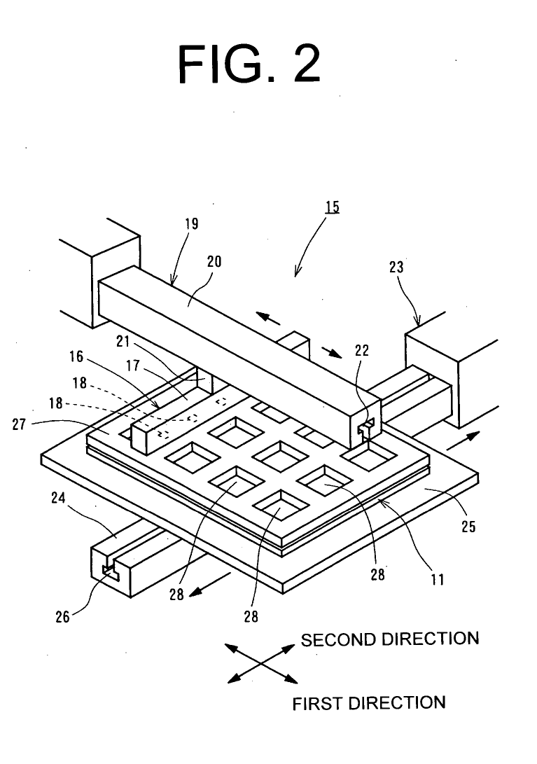

The film formation device 15 shown in FIG. 2 is for depositing the hole injection layer 13a on the glass substrate 11, on which the anode 12 has been formed.

The film formation device 15 includes a chamber (not shown) capable of maintaining a prescribed vacuum level, a deposition source 16 provided in the chamber, a deposition source moving mechanism 19 for reciprocating the deposition source 16, and a substrate moving mechanism 23 for reciprocating the glass substrate 11 in a second direction.

The term “second direction” used herein designates a direction orthogonal to the first direction. Movement of the deposition source 16 in the first direction together with movement of the glass substrate 11 in the second direction allows relative movement of the deposition source 16 and glass substrate 11 in directions including the two directions.

Explanation of the deposition source 16 is given as follows. That is, the deposition source 16 includes an elongated deposition source housing 17 designed to have substantially the same width as that of the glass substrate 11. The deposition source housing 17 is retained by the deposition source moving mechanism 19, which allows the deposition source housing 17 to reciprocate linearly in the first direction as a direction orthogonal to the longitudinal direction of the housing 17 and horizontally relative to the glass substrate 11.

The deposition source housing 17 is capable of housing an organic material as a deposition material. In addition, the deposition source housing 17 has a plurality of circular outlets 18, which are provided in a line along the longitudinal direction of the deposition source housing 17, so as to face the glass substrate 11 below the outlets 18.

Moreover, the deposition source housing 17 is designed to be heated. Heating the deposition source housing 17 vaporizes or sublimes an organic material, and the vaporized or sublimed organic material is emitted through the outlets 18.

Accordingly, the organic material heated in the deposition source housing 17 passes through the outlets 18, resulting in emission of the deposition material of a constant width from the deposition source 16.

The deposition source moving mechanism 19 will now be explained.

The deposition source moving mechanism 19 is for reciprocating the deposition source 16 in the first direction. Deposition source moving mechanism 19 includes a first guide member 20, which is oriented horizontally in the first direction, and a deposition source holder 21, which is attached to the lower surface of the first guide member 20 so as to be movable relative to the first guide member 20.

The first guide member 20 has a guide 22 provided therein to guide the deposition source holder 21, which reciprocates along the first guide member 20.

The deposition source housing 17 is attached to the lower surface of the deposition source holder 21. Operation of a drive means (not shown) for movement of the deposition source 16 causes the deposition source holder 21 to reciprocate the first guide member 20. In response to the reciprocation of the deposition source holder 21, the deposition source housing 17 reciprocates in the first direction.

Accordingly, the deposition source 16 is able to reciprocate linearly by way of the deposition source moving mechanism 19 and further emits the organic material, which is vaporized or sublimed, through the outlets 18 to the glass substrate 11 in the shape of a strip, as if a curtain flow of the organic material were emitted.

It is noted that a distance of the deposition source housing 17 movement along the first guide member 20 is substantially the same as the length of the glass substrate 11 in the first direction.

Moreover, the drive means for movement of the deposition source 16 may be an appropriate means for reciprocating the deposition source 16. Preferably, the drive means allows the source to move at a constant speed or at a variable speed.

Next, the substrate moving mechanism 23 will be explained.

The substrate moving mechanism 23 is for reciprocating the glass substrate 11 in the second direction. The substrate moving mechanism 23 includes a second guide member 24, which is oriented horizontally in the second direction, and a substrate holder 25, which is attached to the upper surface of the second guide member 24, so as to be movable relative to the second guide member 24.

The second guide member 24 has a guide 26 provided therein to guide the substrate holder 25, which reciprocates along the second guide member 24.

Further, the substrate holder 25 allows the glass substrate 11 to be attached to the upper surface thereof. Operation of the drive means (not shown) for movement of the glass substrate 11 causes the substrate holder 25 to reciprocate relative to the second guide member 24. In response to the reciprocation of the substrate holder 25, the glass substrate 11 reciprocates in the second direction.

Means similar to the drive means for movement of the deposition source 16 may be employed as the drive means for movement of the glass substrate 11.

It is noted that in this embodiment, a distance of the glass substrate 11 movement is substantially the same as a pitch of the outlets 18 provided in the deposition source housing 17.

It is preferred that movement speeds of the glass substrate 11 and the deposition source 16 are designed not to allow the movement of the glass substrate 11, by the substrate moving mechanism 23, and the movement of the deposition source 16, by the aforementioned deposition source moving mechanism 19, to be in synchronism with each other. It is noted that regarding the movement of the glass substrate 11 and the movement of the deposition source 16, the expression “in synchronism with each other” means that a point on the deposition source 16 traces the same trail.

For example, the outlet 18 never needs to leave the same trail on the glass substrate 11 during the reciprocation of the deposition source 16 and a distribution of film thickness of the deposition layer of an organic material should be as uniform as possible.

As described above, in this embodiment, the deposition material of a constant width is emitted in the shape of a strip from the deposition source 16. The deposition source 16 and glass substrate 11 are moved relatively to each other in directions including the first direction, which is orthogonal to the width direction of the strip of the deposition material emitted in the shape of a strip, and the second direction, which is different from the first direction. In the film formation device 15, the relative movement of the deposition source 16 and the glass substrate 11 is realized by the deposition source moving mechanism 19 and the substrate moving mechanism 23. A combination of the deposition source moving mechanism 19 and the substrate moving mechanism 23 is a relative movement enabling means. As a result, the film formation device 15 includes the relative movement enabling means.

A mask 27 of this embodiment is substantially the same as the glass substrate 11 in size and has a plurality of openings 28 for forming a deposition layer in a desired pattern. In this case, the opening 28 is shaped into a rectangle.

The mask 27 is interposed between the deposition source 16 and the glass substrate 11 during deposition of an organic material. In this embodiment, the mask 27 is placed on the glass substrate 11.

Next, operation of the film formation device 15 of the embodiment will be explained.

It is noted that the explanation provides an example of how the hole injection layer 13a, as a part of the organic layer 13, is formed on the glass substrate 11, on which the anode 12 has been formed.

First, the mask 27 is attached to the glass substrate 11, on which the anode 12 has been formed. The glass substrate 11 is placed on the substrate holder 25, in a chamber to fix both components to each other. Then, a predetermined vacuum level is maintained in the chamber.

Thereafter, the deposition source housing 17 is heated to emit an organic material, as a material for the hole injection layer 13a through the outlets 18.

Then, operation of the deposition source moving mechanism 19 causes the deposition source housing 17, on the deposition source holder 21, to move linearly and horizontally in the first direction along the upper surface of the mask 27. Simultaneously, operation of the substrate moving mechanism 23 causes the glass substrate 11 to move in the second direction.

Thus, the deposition source 16 and the glass substrate 11 are moved relatively to each other in directions including two different directions, i.e., the first direction and the second direction.

At this point, the deposition source housing 17 moving in the first direction, by the deposition source moving mechanism 19, passes above the openings 28 of the mask 27 moving in the second direction, and the organic material from the deposition source housing 17 is emitted in the shape of a strip onto the glass substrate 11.

The emitted organic material passes through the openings 28 of the mask 27 and is evaporated on the glass substrate 11.

Then, the reciprocations of the deposition source housing 17 and the glass substrate 11 are repeated in their respective directions, causing the trails of the outlets 18 to be different. Therefore, the organic material emitted from the deposition source housing 17 is deposited uniformly over the glass substrate 11.

The film formation method and film formation device 15 according to the embodiment produce the following beneficial effects.

The deposition source housing 17 and the glass substrate 11 are moved relatively to each other in directions, which includes the first direction orthogonal to the width direction of the strip of the organic material emitted in the shape of a strip and the second direction different from the first direction. As a result, the glass substrate 11 reciprocates by a distance corresponding substantially to a pitch of the outlets 18 by the substrate moving mechanism 23. Furthermore, the deposition source housing 17 reciprocates by the distance corresponding substantially to the length of the glass substrate 11, by the deposition source moving mechanism 19. In addition, since the glass substrate 11 and the deposition source 16 move so that their movements are not in synchronism with each other, the trails of the outlets 18 on the glass substrate 11 are never the same. Therefore, the deposition material emitted in the shape of a strip from the deposition source 16 is deposited uniformly over the glass substrate 11.

Accordingly, the deposition layer obtained by depositing the organic material on the glass substrate 11 is desirably formed to have a uniform distribution of film thickness.

Furthermore, interposing the mask 27 between the glass substrate 11 and the deposition source 16 allows the deposition layer having a desired pattern to be formed on the glass substrate 11.

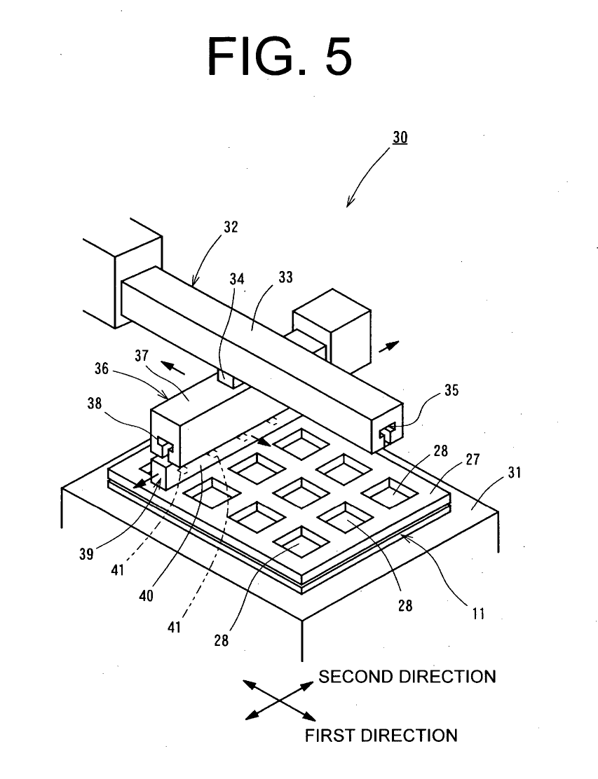

A film formation device 30 of a second embodiment will now be explained with reference to FIG. 5.

This embodiment is an example in which a glass substrate 11 is not moved and the position thereof in a chamber is fixed, and a deposition source 39 is moved relative to the glass substrate 11 in directions including the first direction and the second direction.

In this embodiment, for convenience of explanation, the same numeric designations are given to common parts that were previously explained in the first embodiment. An explanation of the configuration of parts in common with the first embodiment is omitted.

As shown in FIG. 5, the film formation device 30 of the embodiment has a substrate mounting table 31 as a substrate fixing means, a first deposition source moving mechanism 32, and a second deposition source moving mechanism 36.

The substrate mounting table 31 is for placing thereon the glass substrate 11 and a mask and for fixing those components to each other. The position of the substrate mounting table 31 is fixed in a chamber.

The first deposition source moving mechanism 32 is for reciprocating the deposition source 39 in the first direction and includes a first guide member 33, which is oriented parallel to the first direction, and a moving member 34, which is provided on the lower surface of the first guide member 33 so as to be movable relative to the first guide member 33.

The first guide member 33 includes a guide 35 for guiding the moving member 34 and a drive unit (not shown) for movement of the moving member 34, which allows the moving member 34 to reciprocate along the first guide member 33.

The second deposition source moving mechanism 36 is attached to the lower surface of the moving member 34. The moving member 34 reciprocates relative to the first guide member 33. In response to the reciprocation of the moving member 34, the second deposition source moving mechanism 36 reciprocates in the first direction.

The second deposition source moving mechanism 36 is for reciprocating the deposition source 39 in the second direction and includes a second guide member 37, which is oriented parallel to the second direction, and a deposition source holder (not shown) provided on the lower surface of the second guide member 37 so as to be movable relative to the second guide member 37.

The second guide member 37 includes a guide 38 for guiding the deposition source holder which reciprocates along the second guide member 37.

A deposition source housing 40 is attached to the lower surface of the deposition source holder. Operation of a drive means (not shown) for movement of the deposition source holder causes the deposition source holder to reciprocate relative to the second guide member 37. In response to the reciprocation of the deposition source holder, the deposition source housing 40 reciprocates in the second direction.

It should be noted that in this embodiment, a distance of the deposition source housing 40 movement along the first guide member 33 is substantially the same as the length of the glass substrate 11 in the first direction. A distance of the deposition source housing 40 movement along the second guide member 37 is substantially the same as a pitch of the circular outlets 41 provided in the deposition source housing 40.

Moreover, for the same reason as in the first embodiment, it is preferred that the movement of the moving member 34, by the first deposition source moving mechanism 32, and the movement of the deposition source holder, by the second deposition source moving mechanism 36, are not in synchronism with each other.

In this embodiment, the deposition material of a constant width is emitted in the shape of a strip from the deposition source 39. The deposition source 39 is moved relative to the fixed glass substrate 11 in directions including a first direction, which is orthogonal to the width direction of the strip of the deposition material emitted in the shape of a strip, and a second direction, which is different from the first direction. Therefore, in the film formation device 30, the relative movement of the deposition source housing 40 to the glass substrate 11 is realized by the first deposition source moving mechanism 32 and the second deposition source moving mechanism 36. A combination of the first deposition source moving mechanism 32 and the second deposition source moving mechanism 36 is a relative movement enabling means. As a result, the film formation device 30 includes the relative movement enabling means.

According to the film formation device 30 of this embodiment, the first deposition source moving mechanism 32 and the second deposition source moving mechanism 36 cause the deposition source 39 to move relative to the glass substrate 11 and in terms of relative movement of the deposition source 39 and the glass substrate 11. Therefore, it can be concluded that deposition of the organic material to be emitted on the glass substrate 11 is the same as in the first embodiment.

Accordingly, the deposition material emitted in the shape of a strip from the deposition source 39 is deposited uniformly over the glass substrate 11.

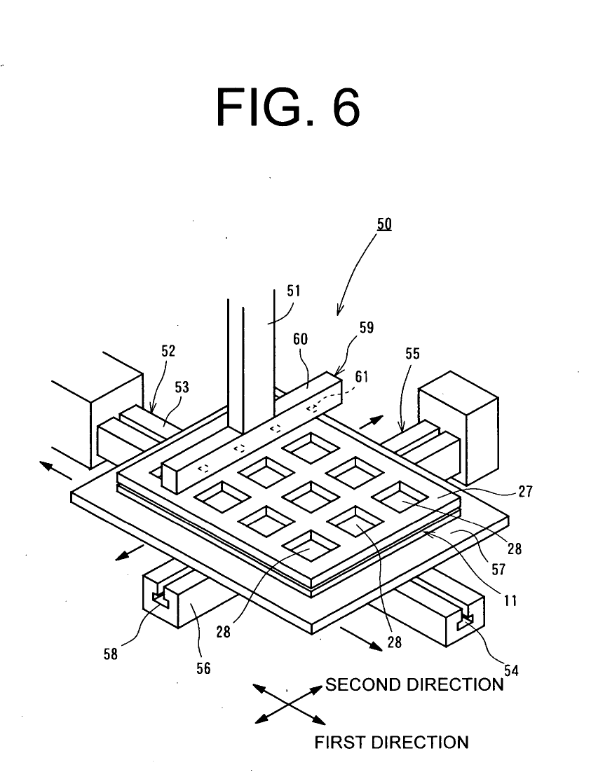

A film formation device 50 of a third embodiment will now be explained with reference to FIG. 6.

This embodiment is an example of a film formation device in which a deposition source 59 is not moved and the position thereof in a chamber is fixed. A glass substrate 11 is moved relative to the deposition source 59 in directions including a first direction and a second direction.

For convenience of explanation, the same numeric designations are used for parts in common with the first embodiment. An explanation of the configuration of parts in common with the first embodiment is omitted.

As shown in FIG. 6, the film formation device 50 of this embodiment has a deposition source fixing rod 51 as a deposition source fixing means, a first substrate moving mechanism 52, and a second substrate moving mechanism 55.

The deposition source fixing rod 51 is for hanging and fixing thereto a deposition source housing 60 and the position thereof is fixed in a chamber.

The first substrate moving mechanism 52 is for reciprocating the glass substrate 11 in the first direction and includes a first guide member 53, which is oriented parallel to the first direction, and a moving member (not shown), which is provided on the upper surface of the first guide member 53 so as to be movable relative to the first guide member 53.

The first guide member 53 includes a guide 54 for guiding the moving member, and a drive means (not shown) for movement of the moving member, which causes the moving member to reciprocate along the first guide member 53.

The second substrate moving mechanism 55 is attached to the upper surface of the moving member. The moving member reciprocates relative to the first guide member 53, and in response to the reciprocation of the moving member, the second substrate moving mechanism 55 reciprocates in the first direction.

The second substrate moving mechanism 55 is for reciprocating the glass substrate 11 in the second direction and includes a second guide member 56, which is oriented parallel to the second direction, and a substrate holder 57, which is provided on the upper surface of the second guide member 56 so as to be movable relative to the second guide member 56.

The second guide member 56 includes a guide 58 for guiding the substrate holder 57, which reciprocates along the second guide member by a drive means (not shown) for movement of the substrate holder 57.

The glass substrate 11 is attached to the upper surface of the substrate holder 57. The substrate holder 57 reciprocates relative to the second guide member 56, and in response to the reciprocation of the substrate holder 57, the glass substrate 11 reciprocates in the second direction.

It should be noted that in the embodiment, a distance of the moving member movement along the first guide member 53 is substantially the same as the length of the glass substrate 11 in the first direction. A distance of the glass substrate 11 movement in the second direction along the second guide member 56 is substantially the same as a pitch of circular outlets 61 provided in the deposition source housing 60.

Moreover, for the same reason as in the aforementioned embodiment, it is preferred that the movement of the moving member by the first substrate moving mechanism 52 and the movement of the substrate holder 57 by the second substrate moving mechanism 55 are not in synchronism with each other.

In this embodiment, the organic material of a constant width is emitted in the shape of a strip from the deposition source 59. The glass substrate 11 is moved relative to the fixed deposition source 59 in directions including the first direction, which is orthogonal to the width direction of the strip of the organic material emitted in the shape of a strip, and the second direction, which is different from the first direction. Therefore, in the film formation device 50, the relative movement of the glass substrate 11 to the deposition source 59 is realized by the first substrate moving mechanism 52 and the second substrate moving mechanism 55. A combination of the first substrate moving mechanism 52 and the second substrate moving mechanism 55 is a relative movement enabling means. As a result, the film formation device 50 includes the relative movement enabling means.

Further, according to the film formation device 50 of this embodiment, the first substrate moving mechanism 52 and the second substrate moving mechanism 55 cause the glass substrate 11 to move relative to the deposition source 59 and in terms of relative movement of the deposition source 59 and glass substrate 11. It can be concluded that deposition of the organic material to be emitted on the glass substrate 11 is the same as in the first and second embodiments.

Accordingly, the organic material emitted in the shape of a strip from the deposition source 59 is deposited uniformly over the glass substrate 11.

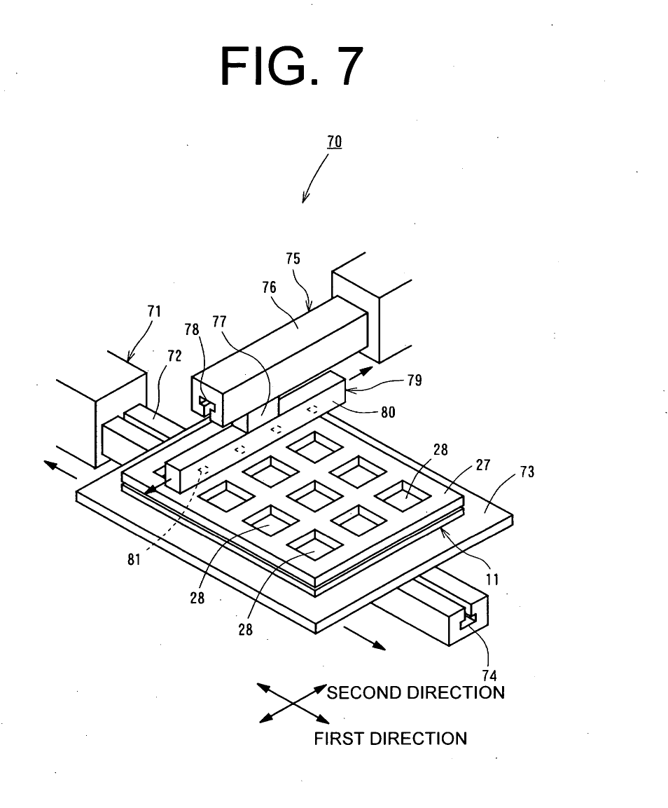

A film formation device 70 of a fourth embodiment will now be explained with reference to FIG. 7.

The embodiment is an example of a film formation device in which a glass substrate 11 reciprocates in a first direction and a deposition source 79 reciprocates relative to the glass substrate 11 in a second direction.

For convenience of explanation, the same numeric designations are used for parts in common with the first embodiment. An explanation of the configuration of parts in common with the first embodiment is omitted.

As shown in FIG. 7, the film formation device 70 of the embodiment essentially includes a substrate moving mechanism 71, for moving the glass substrate 11 in the first direction, and a deposition source moving mechanism 75, for moving a deposition source housing 80 in the second direction.

The substrate moving mechanism 71 is for reciprocating the glass substrate 11 in the first direction and includes a first guide member 72, which is oriented parallel to the first direction, and a substrate holder 73, which is provided on the upper surface of the first guide member 72 so as to be movable relative to the first guide member 72.

The first guide member 72 includes a guide 74, for guiding the substrate holder 73, and a drive means (not shown), for movement of the substrate holder 73, which causes the substrate holder 73 to reciprocate along the first guide member 72.

Further, the deposition source moving mechanism 75 having a deposition source 79 is provided above the substrate holder 73. The deposition source moving mechanism 75 is for reciprocating the deposition source 79 in the second direction and includes a second guide member 76, which is oriented parallel to the second direction, and a deposition source holder 77, which is provided on the lower surface of the second guide member 76, so as to be movable relative to the second guide member 76.

The second guide member 76 includes a guide 78, for guiding the deposition source holder 77, and a drive means (not shown), for movement of the deposition source holder 77, which causes the deposition source holder 77 to reciprocate along the second guide member 76.

The deposition source housing 80 is attached to the lower surface of the deposition source holder 77 and the deposition source holder 77 reciprocates relative to the second guide member 76. In response to the reciprocation of the deposition source holder 77, the deposition source housing 80 reciprocates in the second direction.

It should be noted that in the embodiment, a distance of the glass substrate 11 movement along the first guide member 72 is substantially the same as the length of the glass substrate 11 in the first direction. A distance of the deposition source housing 80 movement in the second direction along the second guide member 76 is substantially the same as a pitch of outlets 81 provided in the deposition source housing 80.

Moreover, for the same reason as in the first and second embodiments, it is preferred that the movement of the glass substrate 11, by the substrate moving mechanism 71, and the movement of the deposition source housing 80, by the deposition source moving mechanism 75, are not in synchronism with each other.

In this embodiment, the organic material of a constant width is emitted in the shape of a strip from the deposition source 79. The glass substrate 11 and the deposition source 79 are moved relatively to each other in directions including the first direction, which is orthogonal to the width direction of the strip of the organic material emitted in the shape of a strip, and the second direction, which is different from the first direction. Therefore, in the film formation device 70, the movement of the glass substrate 11 is realized by the substrate moving mechanism 71 and the movement of the deposition source 79 is realized by the deposition source moving mechanism 75. A combination of the substrate moving mechanism 71 and the deposition source moving mechanism 75 is a relative movement enabling means. As a result, the film formation device 70 includes the relative movement enabling means.

According to the film formation device 70 of this embodiment, the substrate moving mechanism 71 causes the glass substrate 11 to move in the first direction and the deposition source moving mechanism 75 causes the deposition source 79 to move in the second direction. In terms of relative movement of the deposition source 79 and the glass substrate 11, it can be concluded that deposition of the organic material to be emitted on the glass substrate 11 is the same as in the first to third embodiments.

Accordingly, the deposition material emitted in the shape of a strip from the deposition source 79 is deposited uniformly over the glass substrate 11.

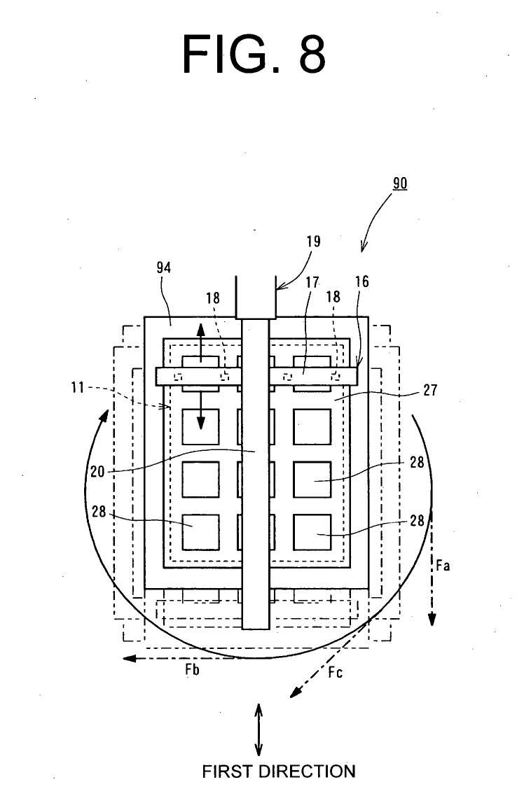

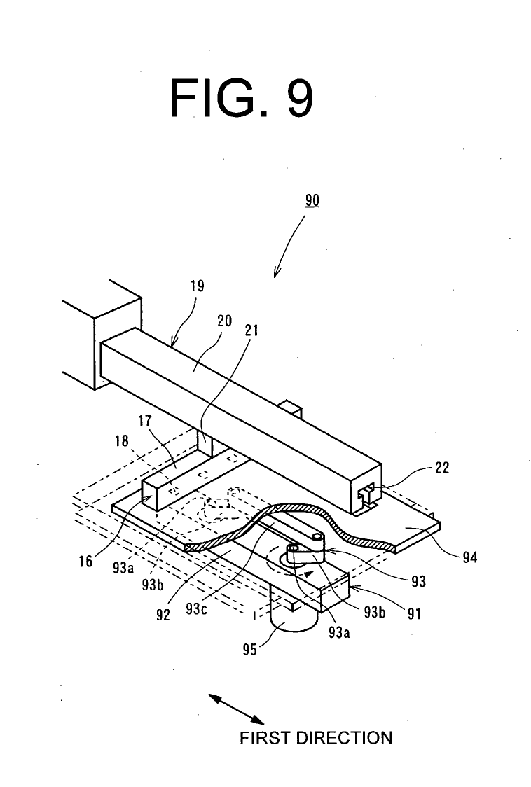

A film formation device 90 of a fifth embodiment will now be explained with reference to FIG. 8 and FIG. 9.

This embodiment is an example in which a deposition source 16 reciprocates in a first direction while a glass substrate 11 moves in directions including a second direction. During relative movement of the deposition source 16 and the glass substrate 11, the second direction in which the glass substrate 11 moves changes with respect to time. In more detail, the glass substrate 11 is moved to leave a circular trail while the orientation thereof is maintained.

In this embodiment, for convenience of explanation, the same numeric designations are used for parts in common with the first embodiment. An explanation of the configuration parts in common with the first embodiment is omitted.

In FIG. 9, a mask 27 and the glass substrate 11 are not shown, however, during deposition, the mask 27 and glass substrate 11 are used.

The film formation device 90 of this embodiment shown in FIG. 8 and FIG. 9 essentially includes a chamber, a deposition source 16, a deposition source moving mechanism 19, and a substrate moving mechanism 91.

The configuration of the deposition source 16 and the deposition source moving mechanism 19 is the same as that of the first embodiment and therefore explanation thereof is omitted. An explanation is now given of the substrate moving mechanism 91.

As shown in FIG. 9, the substrate moving mechanism 91 of this embodiment essentially includes a base 92, a parallel linkage 93 provided on a base 92, a substrate holder 94 attached to the parallel linkage 93, and a drive unit 95.

The position of the base 92 is fixed in the chamber. The parallel linkage 93 is provided on the base 92. The drive unit 95, for operation of the parallel linkage 93, is mounted to the base 92.

An explanation of the parallel linkage 93 on the base 92 is now provided. The parallel linkage 93 includes a pair of rotary shafts 93a, which are provided vertically on the upper surface of the base 92 so as to keep a predetermined distance therebetween. A pair of rotary arms 93b is fixed respectively to both of the rotary shafts 93a, and a connection rod 93c, to which free ends of both of the rotary arms 93b are attached.

The rotary arms 93b are attached to the connection rod 93 so as to be parallel to each other. One of the rotary shafts 93a is rotated by the drive unit 95.

Accordingly, when one of the rotary arms 93b is rotated by operation of the drive unit 95, the other of the rotary arms 93b is rotated by way of the connection rod 93c.

When the rotary arms 93b are rotated, the connection rod 93c leaves a circular trail while maintaining its orientation.

Therefore, when the drive unit 95 is operated in a state in which the substrate holder 94 is mounted on the connection rod 93c and the glass substrate 11 is placed on the substrate holder 94, the glass substrate 11 leaves a circular trail while maintaining its orientation.

It should be noted here that in this embodiment, during relative movement of the deposition source 16 and the glass substrate 11, the second direction in which the glass substrate 11 moves changes with respect to time relative to the first direction.

Since the glass substrate 11 is moved by the substrate moving mechanism 91 leaving a circular trail, it can be concluded that change of the second direction relative to the first direction in the embodiment includes a range of from 0 to 360 degrees.

For instance, as shown in FIG. 8, the second direction for the glass substrate 11 includes directions such as a direction Fa, which is aligned with the first direction, a direction Fb, which is orthogonal to the first direction, and a direction Fc, which is oriented 45 degrees relative to the first direction.

Consequently, it could be concluded that the substrate moving mechanism 91 of this embodiment is a direction changing mechanism for changing the second direction in which the glass substrate 11 moves.

It should be noted that in the embodiment, a distance of a deposition source housing 17 movement along a first guide member 20 is substantially the same as the length of the glass substrate 11 in the first direction.

The length of the rotary arms 93b of the substrate moving mechanism 91 is substantially the same as half a pitch of outlets 18 provided in the deposition source housing 17.

Accordingly, when the second direction for the glass substrate 11 is aligned with the first direction, a distance of the glass substrate 11 movement in a direction orthogonal to the first direction is substantially the same as the pitch of the outlets 18.

In the embodiment, an organic material of a constant width is emitted in the shape of a strip from the deposition source 16, the glass substrate 11 is moved in directions including the second direction that changes during relative movement, and the deposition source 16 is moved relative to the glass substrate 11 in the first direction, and further, in the film formation device 90, the movement of the deposition source 16 is realized by the deposition source moving mechanism 19 and the movement of the glass substrate 11 is realized by the substrate moving mechanism 91.

Therefore, it could be concluded that a combination of the deposition source moving mechanism 19 and substrate moving mechanism 91 is a relative movement enabling means and as a result, the film formation device 90 includes the relative movement enabling means, and further, the relative movement enabling means includes the direction changing mechanism.

Further, according to the film formation device 90 of the embodiment, the deposition source moving mechanism 19 and the substrate moving mechanism 91 cause the deposition source 16 to move relative to the glass substrate 11 and in terms of relative movement of the deposition source 16 and the glass substrate 11, it can be concluded that deposition of the organic material to be emitted on the glass substrate 11 is substantially the same as in the first to fourth embodiments.

Accordingly, the organic material emitted in the shape of a strip from the deposition source 16 is deposited uniformly over the glass substrate 11.

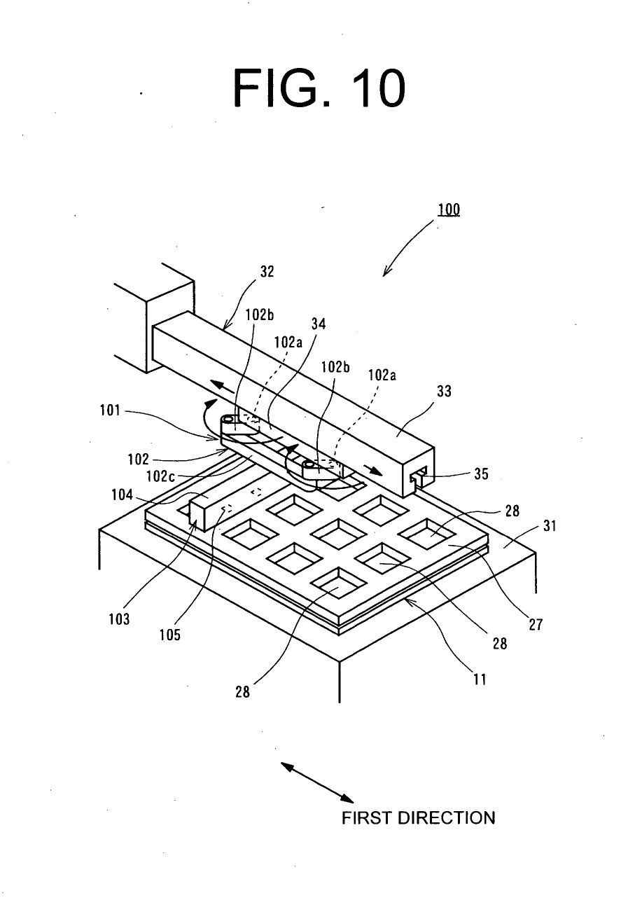

A film formation device 100 of a sixth embodiment will now be explained with reference to FIG. 10.

This embodiment is an example of a film formation device in which a glass substrate 11 is not moved and the position thereof in a chamber is fixed. A deposition source 103 is moved relative to the glass substrate 11 in directions including a first direction and a second direction.

For convenience of explanation, the same numeric designations are used for parts in common with the first and second embodiments. An explanation of the configuration pars in common with those embodiments is omitted.

As shown in FIG. 10, the film formation device 100 of this embodiment has a substrate mounting table 31 as a substrate fixing means, a first deposition source moving mechanism 32, and a second deposition source moving mechanism 101.

Since the substrate mounting table 31 and the first deposition source moving mechanism 32 are substantially the same as those of the second embodiment, an explanation will be given of the second deposition source moving mechanism 101.

The second deposition source moving mechanism 101 is for moving the deposition source 103 in the second direction. The second deposition source moving mechanism 101 of this embodiment is provided on a lower surface of a moving member 34, which is involved in the first deposition source moving mechanism 32 and includes a parallel linkage 102 of the same type as the parallel linkage 93 explained in the description of the fifth embodiment.

The parallel linkage 102 includes a pair of rotary shafts 102a, a pair of rotary arms 102b, and a connection rod 102c, and a deposition source housing 104, which is attached to the lower surface of the connection rod 102c.

The moving member 34 reciprocates relative to the first guide member 33 while the second deposition source moving mechanism 101 moves in the second direction. As a result, the deposition source 103 leaves a circular trail while maintaining its orientation.

Consequently, the second direction in which the deposition source 103 moves changes with respect to time. The second deposition source moving mechanism 101 of this embodiment, during relative movement of the deposition source 103 and the glass substrate 11, is a direction changing means for changing the second direction of the movement of the deposition source 103.

In this embodiment, an organic material of a constant width is emitted in the shape of a strip from the deposition source 103. The deposition source 103 is moved relative to the fixed glass substrate 11 in directions including the first direction, which is orthogonal to the width direction of the strip of the organic material, and the second direction, which changes. Therefore, in the film formation device 100, the relative movement of the deposition source 103 to the glass substrate 11 is realized by the first deposition source moving mechanism 32 and the second deposition source moving mechanism 101.

Accordingly, a combination of the first deposition source moving mechanism 32 and the second deposition source moving mechanism 101 is a relative movement enabling means. As a result, the film formation device 100 includes the relative movement enabling means. Furthermore, the relative movement enabling means includes the direction changing mechanism.

According to the film formation device 100 of this embodiment, the first deposition source moving mechanism 32 and the second deposition source moving mechanism 101 cause the deposition source 103 to move relative to the glass substrate 11 and in terms of relative movement of the deposition source 103 and the glass substrate 11. It can be concluded that deposition of the organic material to be emitted on the glass substrate 11 is the same as in the fifth embodiment.

Accordingly, the organic material from the deposition source 103 is deposited uniformly over the glass substrate 11.

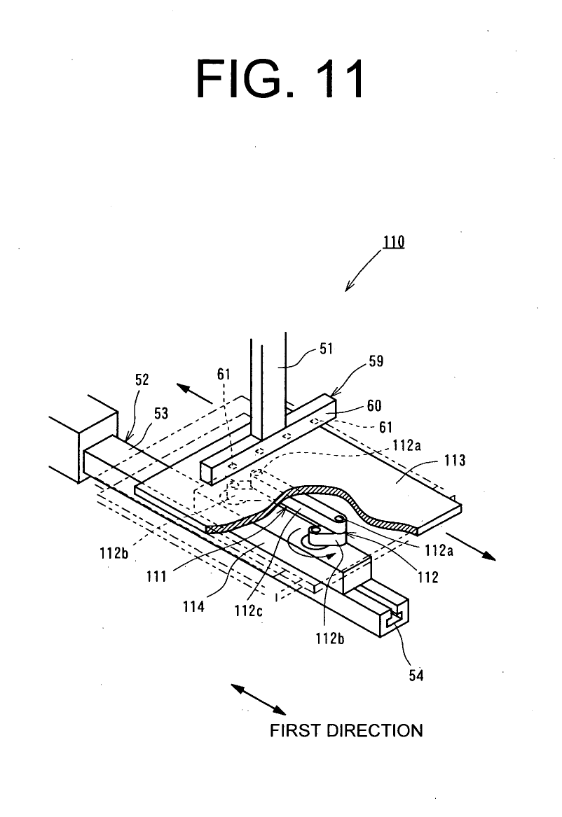

A film formation device 110 of a seventh embodiment will now be explained with reference to FIG. 11.

This embodiment is an example of a film formation device in which a deposition source 59 is not moved and the position thereof in a chamber is fixed. A glass substrate 11 is moved relative to the deposition source 59 in directions including a first direction and a second direction.

For convenience of explanation, the same numeric designations are used for parts in common with the third embodiment. An explanation of the configuration of parts in common with the third embodiment is omitted.

In FIG. 11, a mask 27 and a glass substrate 11 are not shown, however, during deposition, the mask 27 and the glass substrate 11 are used.

The film formation device 110 of this embodiment shown in FIG. 11 has a deposition source fixing rod 51 as deposition source fixing means, a first substrate moving mechanism 52, and a second substrate moving mechanism 111.

Since the deposition source fixing rod 51 and first substrate moving mechanism 52 of the film formation device 110 of the embodiment are substantially the same as those of the third embodiment, an explanation will be given of the second substrate moving mechanism 111 only.

The second substrate moving mechanism 111 is for moving the glass substrate 11 in the second direction. The second substrate moving mechanism 111 of the embodiment is provided on the upper surface of the first substrate moving mechanism 52.

The second substrate moving mechanism 111 includes a base 114 moved by the first substrate moving mechanism 52 and a parallel linkage 112 of the same type as the parallel linkages 93 and 102, which were explained in the description of the fifth and sixth embodiments.

The parallel linkage includes a pair of rotary shafts 112a, a pair of rotary arms 112b, and a connection rod 112c, and a substrate holder 113, which is attached to the upper surface of the connection rod 112c.

The glass substrate 11 reciprocates by the first substrate moving mechanism 52 while the second substrate moving mechanism 111 reciprocates in the second direction. As a result, the glass substrate 11 leaves a circular trail while maintaining its orientation.

Since the second direction in which the glass substrate 11 moves changes with respect to time, the second substrate moving mechanism 111 of this embodiment, during relative movement of the deposition source 59 and the glass substrate 11, is a direction changing mechanism for changing the second direction of the movement of the glass substrate 11.

In the embodiment, an organic material of a constant width is emitted in the shape of a strip from the deposition source 59. The glass substrate 11 is moved relative to the fixed deposition source 59 in directions including the first direction, which is orthogonal to the width direction of the strip of the organic material, and the second direction, which is different from the first direction. In the film formation device 110, the relative movement of the glass substrate 11 to the deposition source 59 is realized by the first substrate moving mechanism 52 and the second substrate moving mechanism 111.

A combination of the first substrate moving mechanism 52 and second substrate moving mechanism 111 is a relative movement enabling means. In addition, the film formation device 110 includes the relative movement enabling means. Furthermore, the relative movement enabling means includes a direction changing mechanism.

According to the film formation device 110 of this embodiment, the first substrate moving mechanism 52 and second substrate moving mechanism 111 cause the glass substrate 11 to move relative to the deposition source 59, in terms of relative movement of the deposition source 59 and glass substrate 11. It can be concluded that deposition of the organic material to be emitted on the glass substrate 11 is the same as in the aforementioned embodiment.

Accordingly, the organic material from the deposition source 59 is deposited uniformly over the glass substrate 11.

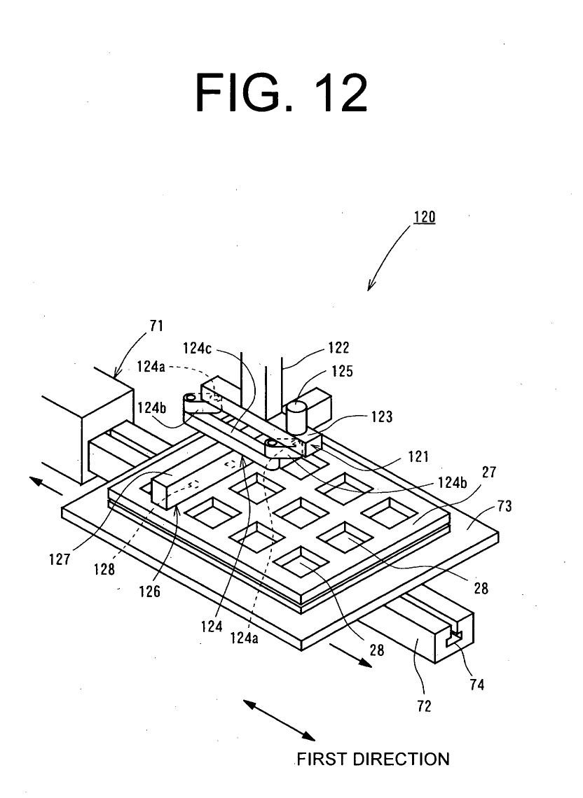

A film formation device 120 of an eighth embodiment will now be explained with reference to FIG. 12.

This embodiment is an example of a film formation device in which a glass substrate 11 reciprocates in a first direction and a deposition source housing 127 moves relative to the glass substrate 11 in a second direction.

For convenience of explanation, the same numeric designations are used for parts in common with the first and fourth embodiments. An explanation of the configuration of parts in common with those embodiments is omitted.

As shown in FIG. 12, the film formation device 120 of this embodiment includes a substrate moving mechanism 71 for moving the glass substrate 11 in the first direction and a deposition source moving mechanism 121 for moving a deposition source 126 in the second direction.

The substrate moving mechanism 71 of this embodiment is for moving the glass substrate in the first direction and is substantially the same as that of the fourth embodiment. Therefore, an explanation thereof is omitted and an explanation will be given of the deposition source moving mechanism 121 only.

The deposition source moving mechanism 121 is for moving the deposition source 126 in the second direction. The deposition source moving mechanism 121 of this embodiment is provided on the lower surface of a fixing member 123 attached to a fixing rod 122, which is provided vertically, and includes a parallel linkage 124 of the same type as the parallel linkage 102, which was explained in the description of the sixth embodiment.

The parallel linkage 124 includes a pair of rotary shafts 124a, a pair of rotary arms 124b, a connection rod 124c, and a deposition source housing 127, which is attached to the lower surface of the connection rod 124c.

Operation of the moving means 123 coupled to the parallel linkage 124 causes the deposition source moving mechanism 121 to move in the second direction, thereby causing the deposition source 124 to leave a circular trail while maintaining its orientation.

Consequently, the second direction in which the deposition source 126 moves changes with respect to time. The deposition source moving mechanism 121 of this embodiment, during relative movement of the deposition source 126 and glass substrate 11, is a direction changing mechanism for changing the second direction of the movement of the deposition source 126.

In this embodiment, an organic material of a constant width is emitted in the shape of a strip from the deposition source 126. The glass substrate 11 is moved in the first direction, which is orthogonal to the width direction of the strip of the organic material emitted in the shape of a strip, while the deposition source 126 is moved relative to the moving glass substrate 11 in directions including the second direction, which changes. In the film formation device 120, the relative movement of the deposition source 126 to the glass substrate 11 is realized by the deposition source moving mechanism 121.

A combination of the deposition source moving mechanism 121 and substrate moving mechanism 71 is a relative movement enabling means. In addition, the film formation device 120 includes the relative movement enabling means. Furthermore, the relative movement enabling means includes a direction changing mechanism.

According to the film formation device 120 of the embodiment, the substrate moving mechanism 71 and deposition source moving mechanism 121 cause the deposition source 126 and glass substrate 11 to be moved relative to each other, and in terms of relative movement of the deposition source 126 and glass substrate 11. It can be concluded that deposition of the organic material to be emitted on the glass substrate 11 is the same as in the aforementioned embodiment.

Accordingly, the organic material emitted in the shape of a strip from the deposition source 126 is deposited uniformly over the glass substrate 11.

An example of the invention will now be explained.

This example is the one in which an organic layer of an organic EL element is formed using a vacuum deposition process on a glass substrate. In this example, a film formation device of the same type as that of the first embodiment was used.

In this example, a glass substrate (substrate size: 320 mm×320 mm) was loaded into a chamber (vacuum level: 10⁻⁴ Pa) and the glass substrate reciprocated in a second direction (movement speed: 3 mm/s, movement distance: 60 mm) while a deposition source (including a housing that is shaped into a rectangular parallelepiped and has a width of 300 mm and five outlets arranged in a line at a pitch of 60 mm) reciprocated in a first direction orthogonal to the second direction (movement speed: 20 mm/s, movement distance: 250 mm), and an organic material was emitted from the deposition source to form a deposition layer on the glass substrate (deposition rate: 12 angstrom/s).

Then, a distribution of film thickness of the deposition layer formed on the glass substrate was measured.

A graph based on results obtained by measurement of the distribution of the film thickness of the deposition layer according to the example is shown in Table 1.

Subsequently, a comparison example will be explained. The comparison example is the one in which a glass substrate does not reciprocate and is fixed in a chamber and conditions other than the movement of the glass substrate are the same as those in the first example.

Then, a distribution of film thickness of a deposition layer formed on the glass substrate was measured.

A graph based on results obtained by measurement of the distribution of the film thickness of the deposition layer according to the comparison example is shown in Table 2.

[image]

[image]

Comparing the distributions of the film thickness of the deposition layers in the first example and the comparison example based on both graphs, it will be clear that the distribution of the film thickness of the deposition layer in the first example is relatively uniform independent of which layer is chosen as the deposition layer.

It could be concluded that this comparison teaches that since the glass substrate moves in the second direction while the deposition source reciprocates in the first direction, the organic material emitted from the deposition source is deposited uniformly over the glass substrate.

On the other hand, in the case of the deposition layer according to the comparison example, waveform-shaped projections and depressions are formed on the surface thereof. This fact teaches that since the glass substrate does not reciprocate in the second direction in the comparison example, the arrangement of the outlets is reflected on the surface of the deposition layer and the organic material emitted from the deposition source is unevenly deposited on the glass substrate.

It should be understood that the invention is in no way limited to the first to eighth embodiments, but may be changed in various ways without departing from the spirit and scope of the invention and for example, the following modifications may be made.

Although in the first to eighth embodiments, the hole transport layer is formed as a part of the organic EL element, the invention is not limited to formation of the hole transport layer, but may be applied to any of the organic layers constituting the organic EL element.

Although in the first to eighth embodiments, the organic layer is deposited to form the organic EL element, the invention is not limited to the deposition of the organic material as a deposition material through use of a vacuum deposition process, but may be applied, for example, to the deposition of an inorganic material.

Although in the first to eighth embodiments, the width of the deposition source housing is designed to correspond substantially to the width of the substrate, it could be possible that for example, a deposition source housing having a width substantially the same as half the width of the substrate is provided and during the movement of the deposition source housing, the deposition source housing moves different distances in back and forth directions. Furthermore, a deposition source housing having an ability to perform a deposition process on a plurality of substrates may be provided so that for example, a deposition source housing having a width substantially the same as twice the width of the substrate is prepared and performs the deposition process on two substrates at a time.

Although in the first to eighth embodiments, the organic material as a deposition material is emitted through the outlets arranged in a line, it could be possible that a deposition source housing having outlets arranged in a plurality of rows such as two or three rows is provided or a plurality of deposition sources are provided in a parallel fashion.

Although in the first to eighth embodiments, the outlet of the deposition source housing is shaped into a circular hole, it could be possible that it is shaped into a rectangular, polygonal or elongated hole.

Although in the first to eighth embodiments, the deposition source is disposed above the glass substrate, it could be possible that the deposition source is disposed so as to cause the outlets thereof to face upward and the glass substrate is disposed thereabove. In this case, positions and/or orientations of the various mechanisms may be appropriately changed.

Although in the first to fourth embodiments, during relative movement of the deposition source and substrate, the second direction relative to the first direction is defined as a direction orthogonal to the first direction, it could be possible that the second direction is defined as directions other than the direction orthogonal to the first direction and in this case, directions oriented close to the direction orthogonal to the first direction are preferable to uniformity of the distribution of the film thickness of the layer formed by deposition from the deposition source.

Although in the first and second embodiments, the distance that the substrate or deposition source moves in the second direction is made to coincide with the pitch of the outlets provided in the deposition source, the distance is not intended to be limited to a particular value and may be appropriately changed depending on various conditions such as a distance between the deposition source and substrate, a deposition rate, etc.

Although in the fifth to eighth embodiments, during relative movement of the deposition source and substrate, the circular trail is illustrated as a result of a change in the second direction, the trail produced as a result of a change in the second direction is not limited to the circular trail but may be, for example, an elliptic trail, circular arc trail or elliptic arc trail.

Although in the fifth to eighth embodiments, during relative movement of the deposition source and substrate, the parallel linkage is used as a means for changing the second direction to cause the corresponding components to leave the circular trail, the invention is not limited to using the parallel linkage, but may, for example, use a means for changing the second direction using a combination of two axis movements.

Therefore, the present examples and embodiments are to be considered as illustrative and not restrictive and the invention is not to be limited to the details given herein but may be modified.

1. A vacuum film formation method for forming a deposition layer by facing a deposition source, which emits a deposition material, and a substrate towards each other, moving the deposition source and the substrate relatively to each other, while keeping an interval between the deposition source and the substrate, and depositing the deposition material from the deposition source onto the substrate, the vacuum film formation method comprising the steps of:
emitting the deposition material of a constant width from the deposition source in the shape of a strip; and
moving the deposition source and the substrate relatively to each other in directions including a first direction, which is orthogonal to a width direction of the strip of the deposition material emitted in the shape of the strip, and a second direction different from the first direction.

2. The vacuum film formation method according to claim 1, wherein the relative movement step includes moving the deposition source and the substrate relatively to each other so as to move the substrate in the second direction while moving the deposition source in the first direction.

3. The vacuum film formation method according to claim 1, wherein the relative movement step includes moving the deposition source and the substrate relatively to each other so as to move the deposition source in the second direction while moving the substrate in the first direction.

4. The vacuum film formation method according to claim 1, wherein the relative movement step includes moving the deposition source relative to the substrate in directions including the first direction and the second direction.

5. The vacuum film formation method according to claim 1, wherein the relative movement step includes moving the substrate relative to the deposition source in directions including the first direction and the second direction.

6. The vacuum film formation method according to claim 1, wherein the relative movement step includes reciprocating the deposition source and the substrate respectively in the first direction and the second direction.

7. The vacuum film formation method according to claim 1, wherein the relative movement step includes changing the second direction.

8. The vacuum film formation method according to claim 1, wherein at least a distance of the relative movement in the first direction is substantially the same as a length of the substrate in the first direction.

9. The vacuum film formation method according the claim 1, wherein a mask is interposed between the substrate and the deposition source.

10. The vacuum film formation method according to claim 1, wherein the deposition layer is an organic layer for an organic electroluminescent element.

11. A vacuum film formation device for forming a deposition layer by emitting a deposition material on a substrate arranged in a chamber, in which a prescribed vacuum level is maintained, the vacuum film formation device comprising:
a deposition source arranged in the chamber for facing the substrate, wherein the deposition source emits the deposition material of a constant width on the substrate in the shape of a strip; and
a relative movement enabling means for moving the deposition source and the substrate relatively to each other in directions including a first direction, which is orthogonal to a width direction of the strip of the deposition material emitted in the shape of the strip, and a second direction different from the first direction.

12. The vacuum film formation device according to claim 11, wherein the relative movement enabling means includes a deposition source moving mechanism for moving the deposition source in the first direction and a substrate moving mechanism for moving the substrate in the second direction.

13. The vacuum film formation device according to claim 11, wherein the relative movement enabling means includes a substrate moving mechanism for moving the substrate in the first direction and a deposition source moving mechanism for moving the deposition source in the second direction.

14. The vacuum film formation device according to claim 11, further comprising a substrate fixing means for fixation of the substrate, wherein the relative movement enabling means includes a first deposition source moving mechanism and a second deposition source moving mechanism for moving the deposition source relative to the substrate in directions including the first direction and the second direction.

15. The vacuum film formation device according to claim 11, further comprising a deposition source fixing means for fixation of the deposition source, wherein the relative movement enabling means includes a first substrate moving mechanism and a second substrate moving mechanism for moving the substrate relative to the deposition source in directions including the first direction and the second direction.

16. The vacuum film formation device according to claim 11, wherein the relative movement enabling means reciprocates the deposition source and the substrate respectively in the first direction and the second direction.

17. The vacuum film formation device according to claim 11, wherein the relative movement enabling means includes a direction changing mechanism for changing the second direction during relative movement of the deposition source and the substrate.

18. The vacuum film formation device according to claim 11, wherein a distance of the relative movement in the first direction has at least a length that is substantially the same as that of the substrate in the first direction.

19. The vacuum film formation device according to claim 11, further comprising a mask interposed between the substrate and the deposition source for deposition.

20. The vacuum film formation device according to claim 11, wherein the deposition source has a plurality of outlets that emit the deposition material therethrough, the outlets being arranged in a line along a direction orthogonal to the first direction.

21. The vacuum film formation device according to claim 11, wherein the deposition layer is an organic layer for an organic electroluminescent element.
